(19) United States
(12) Patent Application Publication
(10) Pub. No.: US 2022/0094876 A1
(43) Pub. Date: Mar. 24, 2022

(54) INPUT COUNTER-OFFSET CIRCUIT FOR OPTO-ELECTRICAL SIGNALS

(71) Applicant: VEO PHOTONICS, INC., San Diego, CA (US)

(72) Inventors: Chen-Kuo Sun, Escondido, CA (US); Jeb M. Binkley, Portland, OR (US); Robert B. Welstand, San Diego, CA (US); Rajat Sharma, San Diego, CA (US)

(21) Appl. No.: 17/031,429

(22) Filed: Sep. 24, 2020

(51) Int. Cl. H04N 5/3745; H01L 27/146; H03F 3/08

(52) U.S. Cl. CPC H04N 5/37455; H03F 3/082; H01L 27/14643

(57) ABSTRACT

Circuitry for an optical receiver includes a photodiode for converting an optical signal into a photocurrent having an AC portion I_{pd}(AC) and a DC portion I_{pd}(DC). The circuitry includes a circuit element that is connected between the photodiode and the input to a Trans-Impedance Amplifier (TIA). Included in the circuit element is an AC bypass capacitor C_{bp} and a sensor. In detail, the sensor may be either a current sensor or a voltage sensor. In either case, the sensor establishes a cancellation current for removing the DC portion I_{pd}(DC) from the photocurrent while the AC bypass capacitor C_{bp} shunts an AC portion I_{pd}(AC) to ground. The result is that only an AC portion I_{pd}(AC) of the optical signal is maintained for input into the TIA.

### FIELD OF THE INVENTION

The present invention pertains generally to optical receivers having photodiodes for converting an optical signal into a photocurrent having an AC portion I_{pd}(AC) and a DC portion I_{pd}(DC), wherein the AC portion I_{pd}(AC) carries a modulated signal. More particularly, the present invention pertains to optical receivers that input only the AC portion I_{pd}(AC) of a modulated photocurrent into a Trans-Impedance Amplifier (TIA), to thereby generate a corresponding electrical signal. The present invention is particularly, but not exclusively, useful as an optical receiver having inter counter-offset circuits for suppressing the DC portion I_{pd}(DC) of a photocurrent prior to inputting the AC portion I_{pd}(AC) into the TIA.

### BACKGROUND OF THE INVENTION

It is well known that the photocurrent generated by a photodiode in response to a modulated optical signal will include both an AC portion, I_{pd}(AC), and a DC portion, I_{pd}(DC). It is also known that the AC portion I_{Pd}(AC) of this photocurrent contains all of the information contained in the modulated optical signal. The consequence of this is that only the AC portion I_{pd}(AC) is actually needed for converting the optical signal into an electrical signal. It therefore follows that, for the signal processing purpose of converting an optical signal into an electrical signal, the DC portion I_{pd}(DC) of the optical signal is superfluous and is sometimes detrimental.

For receiving and amplifying a photocurrent, Trans-Impedance Amplifiers (TIAs) are commonly used in modern optical receiver designs that employ a single photodiode. These DC-coupled TIAs, however, typically require feedback control from the TIA output to compensate for the DC offset that results when an averaged photocurrent is being received at the TIA input. This DC offset contributes to a condition commonly referred to as offset issues. Importantly, it is well known that when offset issues are present, the TIA's circuit bias conditions will vary with the offset current, depending on the optical signal strength; therefore, the performance and the dynamic operational range of the TIA are degraded.

In light of the above, it is an object of the present invention to provide a counter-offset circuit that accomplishes a complete removal of the DC portion I_{pd}(DC) from the averaged photocurrent generated by a photodiode prior to an AC portion I_{pd}(AC) input into the TIA. Another object of the present invention is to eliminate the need for a feedback of TIA output to compensate for the photocurrent offset issue. Yet another object of the present invention is to eventually use an input counter-offset circuit that can incorporate multiple photodiodes and/or multiple TIAs in the optical receiver design. Still another object of the present invention is to provide an input counter-offset circuitry that is easy to assembly, is simple to use, and is comparatively cost effective.

### SUMMARY OF THE INVENTION

In overview, the primary purpose of the present invention is to provide only the AC portion I_{pd}(AC) of a photocurrent that is generated by a photodiode as the input to a TIA. Stated differently, the objective is to counter a DC offset that changes the TIA input bias with respect to the DC portion I_{pd}(DC). Moreover, in accordance with the present invention, this objective is accomplished using only components that are included in a circuit element that is interconnected entirely between the photodiode and the input port of the TIA.

The present invention recognizes that its purpose can be accomplished using either a current sensor or a voltage sensor in the circuit element. Further, the present invention recognizes that the connections between the photodiode and the TIA, via the circuit element, can be established to include either a current sensor or a voltage sensor in the circuit element. Further, the present invention recognizes that the connection between the input port of the TIA and the photodiode can be accomplished with either the cathode or the anode of the photodiode.

Consequently, there are four different embodiments for the present invention that accomplish the same result, i.e., a pure AC portion I_{pd}(AC) input to the TIA. Two of these embodiments employ a current sensor where either the cathode or the anode of the photodiode is connected to the TIA input port. These embodiments employ a current mirror sensor wherein the photocurrent's DC portion I_{pd}(DC) and its image cancel each other at the TIA input. The other embodiments of the present invention both employ a voltage sensor. For both of these embodiments a voltage deviation, ΔV, at the TIA input, which is due to the DC portion I_{pd}(DC) of the photocurrent, is identified by a feedback correction processor. The circuit element then responds to this ΔV change with a feedback cancellation current which can be added or subtracted to the photocurrent. Specifically, the feedback cancellation current is adjusted until the DC portion I_{pd}(DC) in the photocurrent is suppressed and a pure AC portion I_{pd}(AC) is present at the TIA input.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic diagram of the general circuitry for the present invention;

FIG. 2A is a schematic diagram showing components of the circuitry connected, in combination, with the input port and the diode bias port of the TIA, when the circuitry is configured with the anode of the diode connected to the input port of the TIA, and the circuitry includes a current sensor;

FIG. 2B is a schematic of a cancellation circuit having a current mirror sensor for the configuration of the circuitry shown in FIG. 2A;

FIG. 2C is a schematic of a cancellation circuit, having a current mirror sensor and an auxiliary circuit to enhance the mirroring accuracy and stability, for the configuration of the circuitry shown in FIG. 2A;

FIG. 3A is a schematic diagram showing components of the circuitry connected, in combination, with the input port and the diode bias port of the TIA, when the circuitry is configured with the cathode of the diode connected to the input port of the TIA, and the circuitry includes a current sensor;

FIG. 3B is a schematic of a cancellation circuit having a current mirror sensor for the configuration of the circuitry shown in FIG. 3A;

FIG. 3C is a schematic of a cancellation circuit, having a current mirror sensor and an auxiliary circuit to enhance the mirroring accuracy and stability, for the configuration of the circuitry shown in FIG. 3A;

FIG. 4 is a schematic diagram of a representative feedback function for a current correction controller which is used when a voltage sensor is included in the circuit element of the present invention;

FIG. 5 is a schematic diagram of the present invention employing a voltage sensor when the anode of a photodiode is connected to the input port of a TIA; and

FIG. 6 is a schematic diagram of the present invention employing a voltage sensor when the cathode of a photodiode is connected to the input port of a TIA.

### DESCRIPTION OF THE PREFERRED EMBODIMENTS

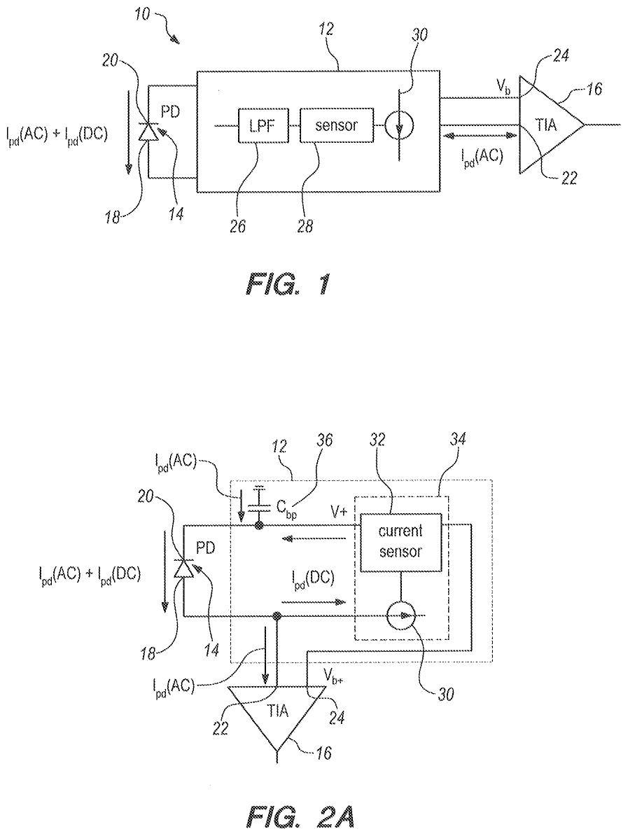

Referring initially to FIG. 1, a circuitry in accordance with the present invention is shown and is generally designated 10. As shown, the circuitry 10 includes a circuit element 12 that is connected between a photodiode (PD) 14 and a Trans-Impedance Amplifier (TIA) 16. Also, as shown, the photodiode 14 has two nodes, an anode 18 and a cathode 20. Further, the TIA 16 includes an input port 22 and a diode bias port 24. In accordance with the present invention the anode 18 and the cathode 20 of the photodiode 14 are connected to the circuit element 12. Also, the input port 22 and the diode bias port 24 of the TIA 16 are connected to the circuit element 12.

Still referring to FIG. 1 it will be appreciated that the circuit element 12 includes a low pass filter (LPF) 26 and a sensor 28 that work together to control a current source 30. For purposes of the present invention, it is this current source 30 which outputs a cancellation current that cancels the unwanted offset issues that are mentioned above in the Background of the Invention, which would otherwise arise at the input port 22 of the TIA 16.

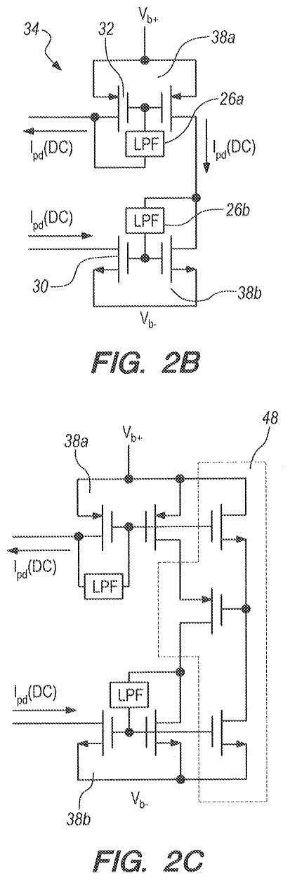

As disclosed in greater detail below, there are several embodiments for the present invention. Individually, these embodiments differ structurally from each other in two important respects. In one, the orientation of the anode 18 and cathode 20 of the photodiode 14 with the circuit element 12 can be reversed. In the other, the sensor 28 that is used for the circuit element 12 can be either a current sensor or a voltage sensor. Thus, there are essentially four different embodiments of the present invention (FIGS. 2A, 3A, 5 and 6, respectively).

FIG. 2A shows an embodiment of the circuit element 12 wherein the anode 18 of the photodiode 14 is connected to the input port 22 of the TIA 16 and the cathode 20 is connected to its diode bias port 24 through a current sensor 32. For the embodiment shown in FIG. 2A, a cancellation circuit 34 includes a current sensor 32 (the sensor 28 in FIG. 1) that interacts with a current source 30. Also, an AC bypass capacitor 36 is connected between the cathode 20 of the photodiode 14 and the current sensor 32. With reference to FIG. 2B it will be seen that the cancellation circuit 34 for this embodiment includes a first filtering mirror 38a that is biased by a voltage V_{b+}. In detail, the first filtering mirror 38a, having a current sensor 32 and a low pass filter 26a, is connected to the cathode 20 of the photodiode 14 with the AC bypass capacitor 36 connected therebetween. The second filtering mirror 38b, having a second low pass filter 26b and a current source 30, is then connected to the anode 18 of the photodiode 14, with the input port 22 of the TIA 16 connected therebetween. The function of AC bypass capacitor 36 is to direct an AC portion I_{pd}(AC) of the photocurrent from cathode 20 to ground, and to direct a DC portion I_{pd}(DC) of the photocurrent to go through the current sensor 32. Further rejection of the AC portion I_{pd}(AC) in the current sensor 32 is accomplished with the low pass filter 26, e.g., connecting a resistor between the drain and the gate of a metal-oxide-semiconductor current sensor 32 together with a shunt capacitor connecting the sensor's gate to ground. In this invention, a low pass filter having a large RC time constant can be monolithically integrated with an ultra-low leakage metal-oxide gate. In a cooperation well known in the pertinent art, the current I_{pd}(DC) (referring to FIGS. 2A and 2B) sensed by the first filtering mirror 38a will be imaged by the second filtering mirror 38b to thereby create a cancellation current which will cancel the DC portion I_{pd}(DC) of the photocurrent prior to inputting the AC portion I_{pd}(AC) into the TIA. The second low pass filter 26b in the second filtering mirror is used to reduce the current noise generated by the current source 30. An alternative cancellation circuit 34 can comprise an auxiliary circuit 48 between filtering mirrors 38a and 38b, as shown in FIG. 2C. This alternative cancellation circuit 34 is provided to improve the current mirroring accuracy and stability over a wide photocurrent operational range.

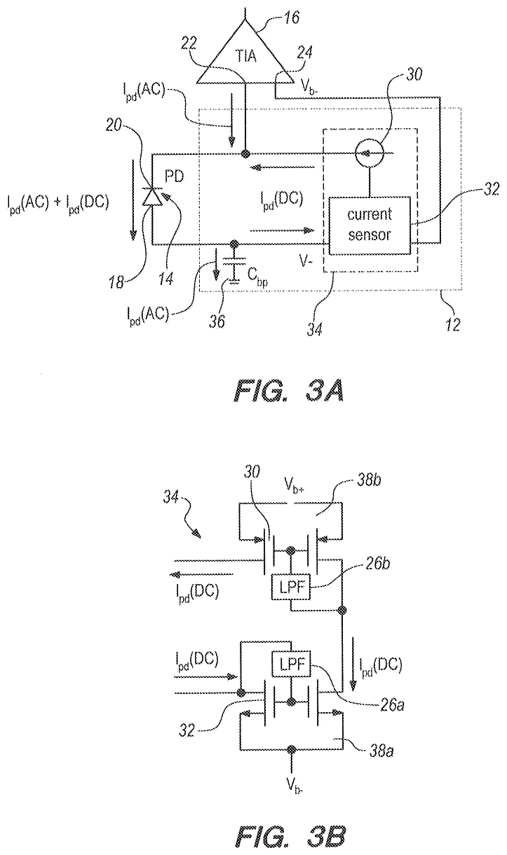

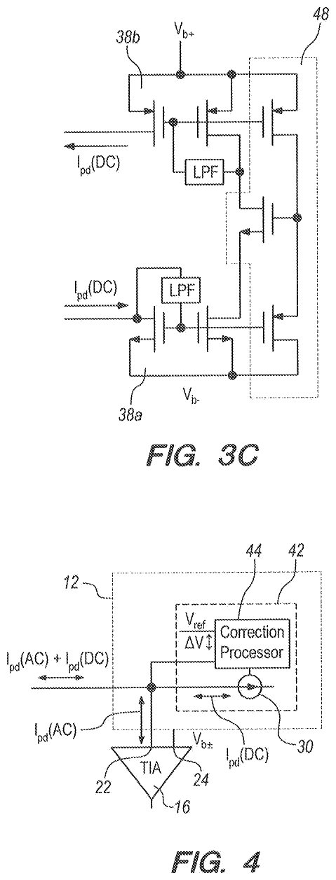

As a generalized mirror image of the circuit element 12 shown in FIG. 2A, FIG. 3A shows an embodiment of the circuit element 12 wherein the cathode 20 of the photodiode 14 is connected to the input port 22 of the TIA 16, and the anode 18 is connected to the diode bias port 24 of the TIA 16. Again, the sensor 28 (in FIG. 1) is a current sensor 32 that interacts with a current source 30. In this embodiment, however, the AC bypass capacitor 36 is connected between the anode 18 of the photodiode 14 and the current sensor 32. Further, with reference to FIG. 3B it will be seen that the first filtering mirror 38a is biased by a voltage V_{b-} and is connected to the anode 18 of the photodiode 14, with the AC bypass capacitor 36 connected therebetween. The second filtering mirror 38b is then connected to the cathode 20 of the photodiode 14 and is biased with a voltage V_{b+}, with the input port 22 of the TIA 16 connected therebetween. Thus, similar to the embodiment shown in FIG. 2A, the current I_{pd}(DC) in the first filtering mirror 38a will be imaged by the second filtering mirror 38b to thereby create a cancellation current which will cancel the DC portion I_{pd}(DC) in the photocurrent prior to inputting the AC portion I_{pd} (AC) into the TIA. The current mirroring accuracy and stability, over a wide photocurrent operational range, can be improved with an alternative cancellation circuit 34 comprising an auxiliary circuit 48 between filtering mirrors 38a and 38b shown in FIG. 3C.

FIG. 4 shows a configuration for the present invention wherein voltage measurements function in combination with a current source 30. Further, for this configuration using a voltage sensor 40 (see FIG. 5), the circuit element 12 receives a bias voltage V_{b±} from the diode bias port 24 of the TIA 16 that depends on the orientation to the anode 18 and the cathode 20 of the photodiode 14 with the circuit element 12.

As shown in FIG. 5, the anode 18 of the photodiode 14 is connected to the input port 22 of the TIA 16. On the other hand, the cathode 20 of the photodiode 14 is connected to an AC bypass capacitor 36. Further, the circuit element 12 is connected to the diode bias port 24 with a bias voltage V_{b+}. Within the cancellation circuit 42 of the circuit element 12, the voltage sensor 40 is connected to a correction processor 44. Further, the voltage sensor 40 is connected via a high impedance low pass filter 26a to the anode 18 of the photodiode 14 and also to the input port 22 of the TIA 16.

In combination, the voltage sensed by the voltage sensor 40 from the anode 18 of the photodiode 14 is provided as an output 46 that is sent to the correction processor 44, where a reference voltage, V_{ref}, is also received by the correction processor 44. In the correction processor 44, the difference between the output 46 from the voltage sensor 40 and the reference voltage V_{ref} is identified as a differential ΔV. This ΔV then generates a correction voltage, connected through a low pass filter 26b, for adjusting a cancellation current output from the current source 30. As in the other embodiments for the present invention, the resultant cancellation current is used for controlling any offset issues occurring at the input port 22 of the TIA 16.

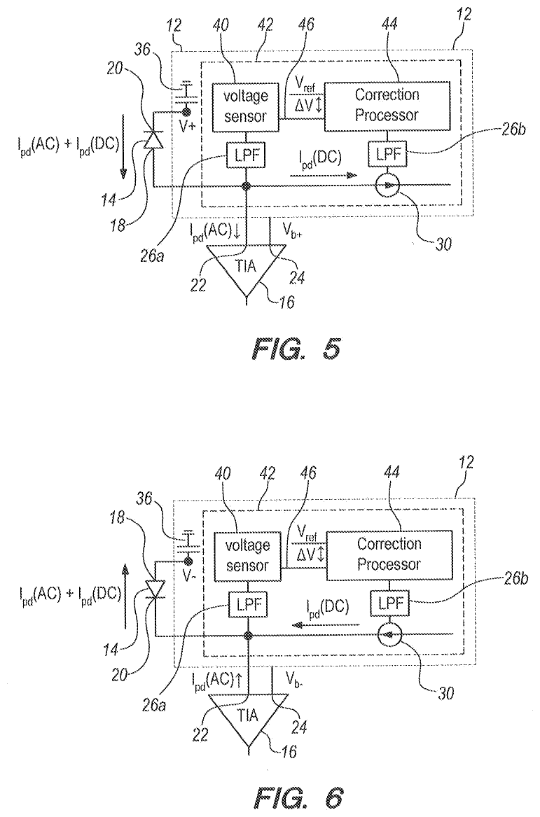

FIG. 6 shows a comparable configuration for a voltage sensor 40 version of the circuit element 12. In the configuration shown in FIG. 6, however, the cathode 20 of the photodiode 14 is connected to the input port 22 of the TIA 16, while the anode 18 of the photodiode 14 is connected to the AC bypass capacitor 36. Further, the circuit element 12 is connected to the diode bias port 24 with a bias voltage V_{b-}. In all other respects the embodiments of the present invention disclosed in FIGS. 5 and 6 function similarly.

In an operation of the present invention, the photodiode 14 generates a photocurrent in response to an optical signal. As a consequence, the photocurrent has an AC portion I_{pd}(AC) and a DC portion I_{pd}(DC). As noted above, the purpose of the present invention is to eliminate the DC portion I_{pd}(DC) from the photocurrent as it enters the input port 22 of the TIA 16. As also noted above, this can be done in accordance with the operation of any one of four different configurations for a circuit element 12.

A simplified operation of the embodiments for the circuit element 12 shown in FIGS. 2A and 3A which use a current sensor 32, can be explained by considering the photocurrent I_{pd}(AC)+I_{pd}(DC) that is generated by the photodiode 14. For these embodiments filtering mirrors 38a and 38b are used to create an image of the DC portion I_{pd}(DC) of the photocurrent from one node of the diode 14. This image current is then fed back into the other node of the diode 14 to cancel (suppress) the DC portion I_{pd}(DC) of the photocurrent prior to its input into the TIA.

Similarly, an operation of embodiments for the circuit element 12 shown in FIGS. 5 and 6 which use a voltage sensor 40, can be explained by again considering the photocurrent I_{pd}(AC)+I_{pd}(DC) that is generated by the photodiode 14. For these embodiments, low pass filters 26a and 26b are used to isolate the voltage sensor 40 and the correction processor 44 from the AC portion I_{pd}(AC) of the photocurrent. In this isolation, the output 46 of the voltage sensor 40 is compared with a reference voltage V_{ref} to identify a differential voltage ΔV. This differential voltage ΔV is then used to adjust a cancellation current until the DC portion I_{pd}(DC) of the photocurrent is suppressed and only the AC portion I_{pd}(AC) of the photocurrent is provided for input to the input port 22 of the TIA 16.

While the particular Input Counter-Offset Circuit for Opto-Electrical Signals as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A circuitry which comprises:
a Trans-Impedance amplifier (TIA) having an input port and a diode bias port;
a photodiode having an anode and a cathode for generating a photocurrent in response to an optical signal, wherein the photocurrent has an AC portion, I_{pd}(AC), and a DC portion, I_{pd}(DC);
a circuit element connected to both the anode and the cathode of the photodiode, and connected to both in the input port and the diode bias port of the TIA;
a sensor included in the circuit element for evaluating the photocurrent generated by the photodiode, to establish a cancellation current for removing the DC portion I_{pd}(DC) from the photocurrent while maintaining the AC portion I_{pd}(AC) for use by the TIA to create an electrical signal; and
at least one low pass filter included in the circuit element, connected between the photodiode and the sensor, to suppress the AC portion I_{pd}(AC) of the photocurrent and to allow the sensor to sense the DC portion I_{pd}(DC) of the photocurrent for establishing the cancellation current.

2. The circuitry of claim 1 wherein the anode of the photodiode is connected to the input port of the TIA and the cathode of the photodiode is connected to the diode bias port of the TIA to provide a bias voltage, V_{b+}, through the circuit element, and wherein the sensor is a current mirror sensor comprising:
a first filtering mirror, including a low pass filter and a current mirror with a sensor, wherein the filtering mirror is connected to the cathode of the photodiode;
an AC bypass capacitor, C_{bp}, connected between the cathode and the first filtering mirror; and
a second filtering mirror, including a current source and a noise reduction low pass filter, connected to the anode of the photodiode with the input port of the TIA connected therebetween, wherein the second filtering mirror images the DC portion I_{pd}(DC) from the first filtering mirror as a cancellation current to remove the DC portion I_{pd}(DC) from the photocurrent for directing the AC portion I_{pd}(AC) in the photocurrent to the input port of the TIA.

3. The circuitry of claim 2 wherein the current sensor mirror is made of a metal-oxide-semiconductor field-effect transistor (MOSFET), and wherein the low pass filter has a resistor connected between the current sensor's gate and drain, and a capacitor between the gate and ground.

4. The circuitry of claim 2 further comprising an auxiliary circuit between the first and the second filtering mirrors to improve the current mirroring accuracy and stability over a side photocurrent operational range.

5. The circuitry of claim 1 wherein the cathode of the photodiode is connected to the input port of the TIA and the anode of the photodiode is connected to the diode bias port of the TIA to provide a bias voltage, V_{b-}, through the circuit element, and wherein the sensor is a current mirror sensor comprising:
a first filtering mirror, including a low pass filter and a current mirror with a sensor, wherein the filtering mirror is connected to the anode of the photodiode, and wherein the first filtering mirror is made of MOSFETs and the low pass filter comprises a resistor between the current sensor's gate and drain, and a capacitor between the gate and ground; and
a second filtering mirror, including a current source and a noise reduction low pass filter, connected to the cathode of the photodiode with the input port of the TIA connected therebetween, wherein the second filtering mirror images the DC portion I_{pd}(DC) from the first filtering mirror as a cancellation current to remove the DC portion I_{pd}(DC) from the photocurrent for directing the AC portion I_{pd}(AC) in the photocurrent to the input port of the TIA.

6. The circuitry of claim 5 further comprising an AC bypass capacitor, C_{bp}, included in the circuit element to shunt the AC portion I_{pd}(AC) to ground, and to pass an averaged photocurrent through the current mirror sensor.

7. The circuitry of claim 1 wherein the sensor is a voltage sensor.

8. The circuitry of claim 7 wherein the anode of the photodiode is connected to the input port of the TIA for using the AC portion I_{pd}(AC) to create the electrical signal, and wherein the circuit element comprises:
a voltage sensor connected with the anode of the photodiode through a high impedance low pass filter;
a correction processor connected to the voltage sensor for comparing a voltage output from the voltage sensor with a predetermined reference value to identify a differential voltage signal ΔV; and
a current source responsive to the correction processor for feeding back a cancellation current until the DC portion I_{Pd}(DC) from the photocurrent is suppressed and only the AC portion I_{pd}(AC) is directed to the input port of the TIA.

9. The circuitry of claim 8 wherein the high impedance low pass filter comprises a resistor (>1KΩ) connected between the TIA input port and the voltage sensor, and a capacitor which shunts the AC portion I_{pd}(AC) of the voltage sensor input to ground.

10. The circuitry of claim 7 wherein the cathode of the photodiode is connected to the input port of the TIA for using the AC portion I_{pd}(AC) to create the electrical signal, and wherein the circuit element comprises:
a voltage sensor connected with the cathode of the photodiode through a high impedance low pass filter;
a correction processor connected to the voltage sensor for comparing a voltage output from the voltage sensor with a predetermined reference value to identify a differential voltage signal ΔV; and
a current source responsive to the correction processor for feeding back a cancellation current to suppress the DC portion I_{pd}(DC) from offsetting the TIA input bias and to direct the AC portion I_{pd}(AC) to the input port of the TIA.

11. A method for assembling a current-offset circuit between a photodiode and a Trans-Impedance Amplifier (TIA) to convert an optical signal into an electric signal, the method comprising the steps of:
providing a photodiode having an anode and a cathode for generating a photocurrent in response to a modulated optical signal, wherein the photocurrent has an AC portion I_{pd}(AC) and a DC portion I_{pd}(DC);
providing a TIA having an input port and a diode bias port; and
connecting a circuit element between the anode and the cathode of the photodiode, and the input port and the diode bias port of the TIA for removing the DC portion I_{pd}(DC) from the photocurrent while maintaining the AC portion I_{pd}(AC) for use by the TIA to create the electrical signal.

12. The method of claim 11 further comprising the steps of:
including a sensor in the circuit element for evaluating the photocurrent generated by the photodiode, to establish a cancellation current for removing the DC portion I_{pd}(DC) from the photocurrent while maintaining the AC portion I_{pd}(AC) for use by the TIA to create an electrical signal; and
connecting at least one low pass filter between the photodiode and the sensor to suppress the AC portion I_{pd}(AC) of the photocurrent and to allow the sensor to sense the DC portion I_{pd}(DC) of the photocurrent for establishing the cancellation current.

13. The method of claim 12 wherein the anode of the photodiode is connected to the input port of the TIA and the cathode of the photodiode is connected to the diode bias port of the TIA to provide a bias voltage, V_{b+}, through the circuit element, and wherein the sensor is a current mirror sensor and the method further comprises the steps of:
connecting a first filtering mirror, including a low pass filter and a current mirror with a sensor, to the cathode of the photodiode; and
connecting a second filtering mirror, including a current source, to the anode of the photodiode with the input port of the TIA connected therebetween, wherein the second filtering mirror images the DC portion I_{pd}(DC) from the first filtering mirror as a cancellation current to remove the DC portion I_{pd}(DC) from the photocurrent for directing the AC portion I_{pd}(AC) in the photocurrent to the input port of the TIA.

14. The method of claim 13 further comprising the step of connecting an AC bypass capacitor, C_{bp}, between the cathode and the first filtering mirror to shunt the AC portion I_{pd}(AC) to ground.

15. The method of claim 12 wherein the cathode of the photodiode is connected to the input port of the TIA and the anode of the photodiode is connected to the diode bias port of the TIA to provide a bias voltage, V_{b-}, through the circuit element, and wherein the sensor is a current mirror sensor and the method further comprises the steps of:
connecting a first filtering mirror, including a low pass filter and a current mirror with a sensor, to the anode of the photodiode; and
connecting a second filtering mirror, including a current source, to the cathode of the photodiode with the input port of the TIA connected therebetween, wherein the second filtering mirror images the DC portion I_{pd}(DC) from the first filtering mirror as a cancellation current to remove the DC portion I_{pd}(DC) from the photocurrent for directing the AC portion I_{pd}(AC) in the photocurrent to the input port of the TIA.

16. The method of claim 15 further comprising the step of connecting an AC bypass capacitor, C_{bp}, included in the circuit element to shunt the AC portion I_{pd}(AC) to ground, and to pass an averaged photocurrent through the current mirror sensor.

17. The method of claim 12 wherein the sensor is a voltage sensor.

18. The method of claim 17 wherein the anode of the photodiode is connected to the input port of the TIA for using the AC portion I_{pd}(AC) to create the electrical signal, and the method further comprises the steps of:
connecting the voltage sensor with the anode of the photodiode through a high impedance low pass filter;
connecting a correction processor to the voltage sensor for comparing a voltage output from the voltage sensor with a predetermined reference value to identify a differential voltage signal ΔV; and
providing a current source responsive to the correction processor for feeding back a cancellation current until the DC portion I_{pd}(DC) from the photocurrent is suppressed and only the AC portion I_{pd}(AC) is directed to the input port of the TIA.

19. The method of claim 18 further comprising the steps of:
connecting a high impedance low pass filter having a resistor (>1KΩ) between the TIA input port and the voltage sensor; and
providing a capacitor which shunts the AC portion I_{pd}(AC) of the voltage sensor input to ground.

20. The method of claim 17 wherein the cathode of the photodiode is connected to the input port of the TIA for using the AC portion I_{pd}(AC) to create the electrical signal, and the method further comprises the steps of:
connecting the voltage sensor to the cathode of the photodiode through a high impedance low pass filter;
connecting a correction processor to the voltage sensor for comparing a voltage output from the voltage sensor with a predetermined reference value to identify a differential voltage signal ΔV; and
providing a current source responsive to the correction processor for feeding back a cancellation current to suppress the DC portion I_{pd}(DC) from offsetting the TIA input bias and to direct the AC portion I_{pd}(AC) to the input port of the TIA.
